(19) United States
(12) Patent Application Publication
(10) Pub. No.: US 2008/0204977 A1
(43) Pub. Date: Aug. 28, 2008

(54) CONNECTOR OPENING COVER WITH REMOVABLE FLEXIBLE PORTIONS

(75) Inventor: JAMES W. TUROCY, ARLINGTON HEIGHTS, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., SCHAUMBURG, IL (US)

(21) Appl. No.: 11/680,014

(22) Filed: Feb. 28, 2007

(51) Int. Cl. H05K 5/00

(52) U.S. Cl. 361/679

(57) ABSTRACT

A connector opening cover is used with an electronic system such as a base radio system. The cover includes a rigid portion having a plurality of openings formed therethrough; and a flexible portion attached to the rigid portion and having a plurality of corresponding removable portions that are located adjacent the plurality of openings, wherein each of at least a subset of the plurality of openings and the corresponding adjacent removable portions have dimensions that correspond to dimensions of a different connector for an electronic system, such that removing the corresponding removable portion allows insertion of the corresponding connector through the cover.

### TECHNICAL FIELD

The technical field relates generally to protecting electronic systems and more particularly to a connector opening cover for an electronic system.

### BACKGROUND

Electronic systems have areas that are populated with a number of system connectors for receiving various mated connectors. Depending on its type, the electronic system may further comprise a cabinet for housing and protecting system components (especially circuit components such as printed circuit boards and the like) from environmental elements including, but not limited to, inclement weather, other types of moisture, dust, dirt and other debris, etc. For base radio systems, for instance, various connectors may be grouped and extend through a given opening in the cabinet for ease of access. Typically, a metal cover (also referred to in the art as a junction panel) is located and secured over this opening in the cabinet. The cover includes a plurality of N smaller openings formed therethrough, with each one of the N openings usually having dimensions corresponding substantially to dimensions of one of N system connectors that could potentially extend through the cabinet opening.

However, depending on the particular radio system implementation, only a portion, M, of the N connectors may actually be used in the system, which results in N-M openings that are not populated with a connector. Usually, each of these N-M openings is required to be covered in some manner to significantly hamper the entry of moisture, debris, etc. into the cabinet and, thereby, prevent damage to the internal system components. It is known to insert individual plastic plugs into each of the N-M openings that are not populated with a connector to cover these openings, but use of such plugs increases the cost of the system due to design and tooling costs associated with creating the plastic plugs.

Thus, there exists a need for a connector opening cover for an electronic system, which addresses at least some of the shortcomings of past and present connector opening cover mechanisms.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments of concepts that include the claimed invention, and to explain various principles and advantages of those embodiments.

FIG. 1 is a schematic diagram of a connector opening cover in accordance with some embodiments.

FIG. 2 is the connector opening cover shown in FIG. 1, and further having some removable portions removed to enable insertion of connectors through the resulting openings.

FIG. 3 is a schematic diagram of a system that includes an electronic system and a connector opening cover secured thereto in accordance with some embodiments.

FIG. 4 is a flow diagram of a method in accordance with some embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments. In addition, the description and drawings do not necessarily require the order illustrated. Apparatus and method components have been represented where appropriate by conventional symbols in the drawings, showing only those specific details that are pertinent to understanding the various embodiments so as not to obscure the disclosure with details that will be readily apparent to those of ordinary skill in the art having the benefit of the description herein. Thus, it will be appreciated that for simplicity and clarity of illustration, common and well-understood elements that are useful or necessary in a commercially feasible embodiment may not be depicted in order to facilitate a less obstructed view of these various embodiments.

### DETAILED DESCRIPTION

Generally speaking, pursuant to the various embodiments, is a connector opening cover, a system that includes the connector opening cover and a method for manufacturing associated with the connector opening cover. The cover includes: a rigid portion having a plurality of openings formed therethrough; and a flexible portion attached to the rigid portion and having a plurality of corresponding removable portions that are located adjacent the plurality of openings in the rigid portion, wherein each of at least a subset of the plurality of openings in the rigid portion and the corresponding adjacent removable portions in the flexible portion have dimensions that correspond to dimensions of a different connector for an electronic system, such that removing the corresponding removable portion allows insertion of the corresponding connector through the cover.

Accordingly, a single cover or a set of covers can be manufactured for a plurality of different applications, wherein certain removable portions are removed to enable insertion of system connectors through the cover. The remaining removable portions remain intact to cover openings in locations where a system connector is not provided. Such a cover can be manufactured using less expensive tooling and less design time and cost than required to implement past and present connector opening cover mechanisms such as the above-described plastic plug solution. Those skilled in the art will realize that the above recognized advantages and other advantages described herein are merely illustrative and are not meant to be a complete rendering of all of the advantages of the various embodiments.

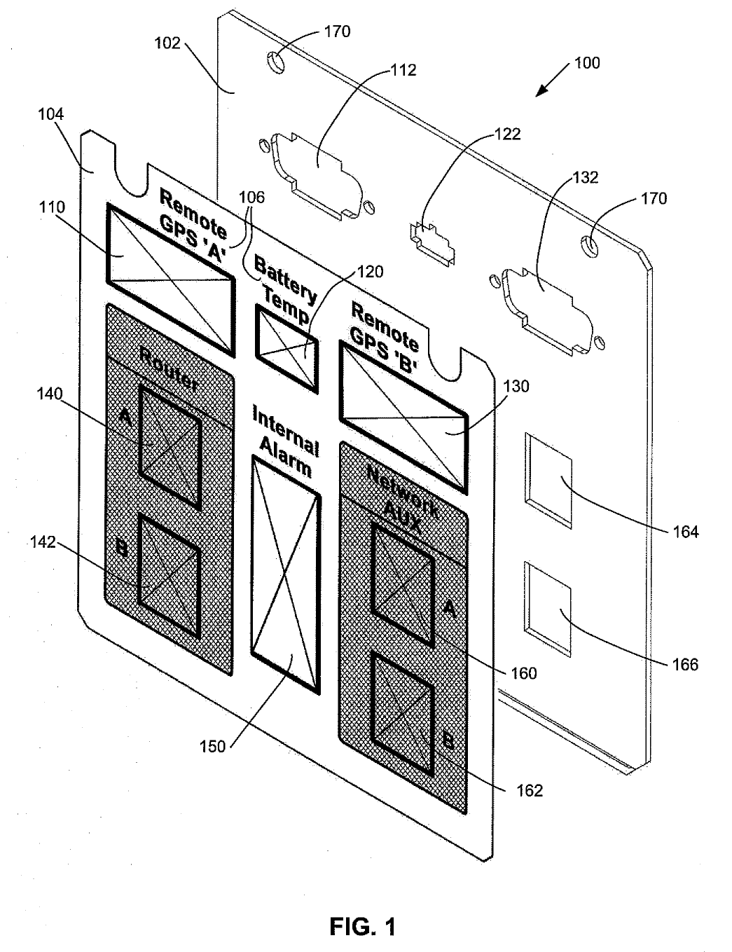

Referring now to the drawings, and in particular FIG. 1, a schematic diagram of a connector opening cover in accordance with some embodiments is shown and indicated generally at 100. Those skilled in the art will recognize and appreciate that the specifics of this example is merely illustrative of some embodiments and that the teachings set forth herein are applicable in a variety of alternative settings. For example, since the teachings described do not depend on the electronic system to which the cover can be attached, they can be applied to any type of electronic system and cover assembly, although an assembly comprising a base radio system is shown in the illustrative embodiments. As such, other alternative implementations of using different types of electronic systems are contemplated and are within the scope of the various teachings described.

Cover 100 comprises a flexible portion 104 that is securedly attached to a rigid portion 102. By a flexible portion, what is meant is that portion 104, as fabricated, is comprised of any suitable material that is pliable and capable of being easily bent without breaking. In an embodiment, the flexible portion comprises a plastic polymer-based material, which may be, for example, a polycarbonate material such as LEXAN®, which is manufactured by GE (General Electrics) Plastics. By a rigid portion, what is meant is that portion 102, as fabricated, is comprised of any suitable material that is stiff, inflexible and unyielding. In an embodiment, the rigid portion comprises a metal or metal alloy, which may be, for example, Cold Rolled Steel.

Rigid portion 102 includes a plurality (two or more) of openings formed therethrough, and flexible portion 104 includes a plurality of corresponding removable portions with each removable portion being positioned adjacent one of the openings in the rigid portion. Cover 100 is shown with eight removable portions 110, 120, 130, 140, 142, 150, 160 and 162. Also shown in FIG. 1 are some of the corresponding openings in rigid portion 102 including an opening 112 (corresponding to removable portion 110), an opening 122 (corresponding to removable portion 120), an opening 132 (corresponding to removable portion 130), an opening 164 (corresponding to removable portion 160), and an opening 166 (corresponding to removable portion 162). The correspondence between the openings in the rigid portion and the removable portions in the flexible portion may be a one-to-one correspondence. Thus, in this case, since there are eight removable portions, there would be eight corresponding openings in the rigid portion. However, a complete one-to-one correspondence between the number of openings in the rigid portion and the number of removable portions is merely illustrative and is not required. Any suitable correspondence is contemplated within the scope of the teachings herein. For example, cover 100 may have a one-to-correspondence between removable portions 110, 120, 130 and 150 and adjacent openings in the rigid portion 102, but have a two-to-one correspondence between removable portions 140 and 142 and a single adjacent opening in the rigid portion 102 and between removable portions 160 and 162 a different single adjacent opening in the rigid portion 102.

Each removable portion and corresponding opening(s) in the rigid portion 102 has dimensions that correspond to a connector (in many instances a different connector) for an electronic system, to enable the connector to extend through the cover upon removing the corresponding removable portion. These connectors are also referred to herein as “system connectors” and are usually some type of electrical connector for joining together electrical circuits within the electronic system to electrical circuits external to the electronic system and can include, plug and socket connectors, DB-9 connectors, DB-25 connectors and USB connectors, to name a few. Connector or system connector as used herein refers to an entire connector assembly or any portion thereof including, but not limited to, any one or more of the mated portions, as well as any cables used with the connector assembly and coupled to the electronic system.

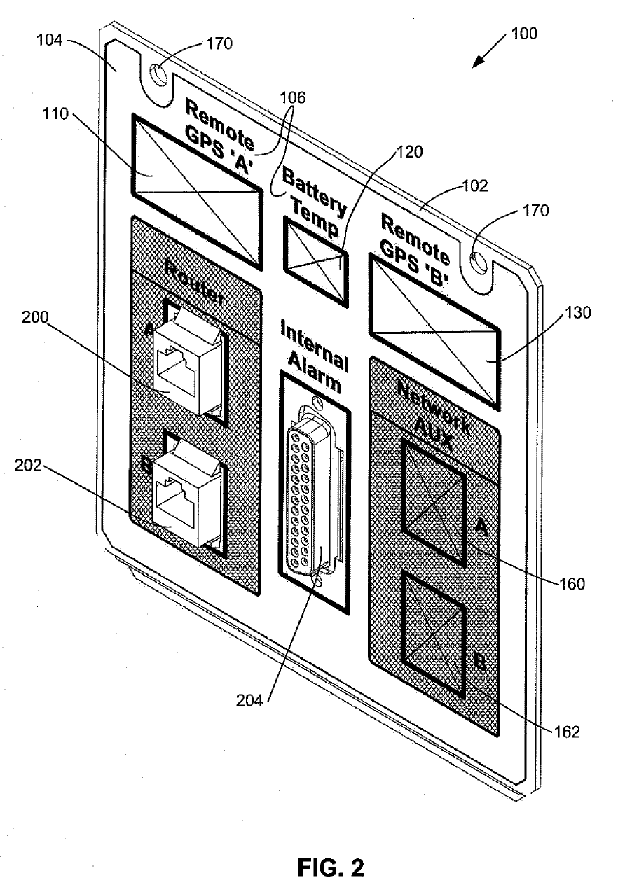

Turning momentarily to FIG. 2, this diagram illustrates the cover 100 further having removable portions 140, 142 and 150 removed to enable insertion, respectively, of connectors 200, 202 and 204 through the resulting openings in the cover. More particularly, illustrated in FIG. 2 is a female socket connector 200 extending through an opening left by removing removable portion 140 and a female socket connector 202 extending through an opening left by removing removable portion 142. Sockets 200 and 202 are electrically coupled to an electronic system (not shown) and respectively receive a mated male plug to complete an electrical connection to the electronic system, during operation of the electronic system. Also shown in FIG. 2 is a D-25 connector 204 electrically coupled to the electronic system and extending through an opening left by removing removable portion 150, which will receive its mated connector during operation of the electronic system. In the embodiment illustrated, the connectors coupled to the electronic system (e.g., 200, 202 and 204) extend through the openings past the surface of the flexible portion 104. However, in other embodiments, the mates to the connectors 200, 202 and 204 may extend through these openings.

As can be readily seen in FIG. 2, the dimensions of each removable portion 140, 142 and 150 are of a suitable size and shape that allow the corresponding system connector to fit through the openings left after removing the removable portion. In an embodiment, there is not a substantial amount of distance between the connector and the perimeter of the removable portion when the connector is inserted through the opening. The corresponding openings in the rigid portion 102 behind the openings resulting from removing 140, 142 and 150 can be the same size as those resulting openings, larger or smaller depending on design specifications for the cover. Moreover, the shape of the openings in the flexible and corresponding rigid portions may be the same or different.

In this illustrative example, the removable portions 140, 142 and 150 and the corresponding openings in the rigid portion and the system connectors 200, 202 and 204 have the following dimensions. The removable portions 140 and 142 are each 23.8 mm×19.0 mm in size, and the corresponding opening in the rigid portion is 18.8 mm×14.7 mm in size. The removable portion 150 is 53.5 mm×21.0 mm in size, and the corresponding opening in the rigid portion is 48.0 mm×16.2 in size. The system connectors 200 and 202 are each 17.0 mm×14.0 mm in size, and the system connector 204 is 48.0 mm×16.2 mm in size. Further to this example, the flexible portion 104 is 132 mm×135.7 mm in size, and the rigid portion is 137 mm×140.7 mm in size. In some implementations, including those illustrated herein, dimensions of some elements are approximate since their shapes are irregular. For example, since connector 204 and the corresponding opening in the rigid portion are not exactly rectangular, their dimensions given above are approximate.

Returning again to FIG. 1, in an embodiment, perforations (e.g., holes, slots) are punched through the flexible portion during manufacturing along a perimeter of each removable portion to enable removal thereof by pushing or punching out the removable portion along its perforations. Ideally, the perforations are of dimensions that enable the removable portions to be easily removed with application of a suitable force, such as by a machine or a finger, but that simultaneously allow the removable portion to otherwise remain intact when no such force is applied.

Flexible portion 104 may further include characters 106 (e.g., representing numbers, letters, etc.), which identify one or more connectors that may be used on the electronic system. In this case, the possible connectors that may be used with the electronic system is a connector for a Remote GPS (Global Positioning System) ‘A’ corresponding to removable portion 110; a connector for a Battery Temperature (“Temp”) corresponding to removable portion 120; a connector for a Remote GPS ‘B’ corresponding to removable portion 130; a connector for one or more Routers corresponding to removable portions 140 and 142; a connector for an Internal Alarm corresponding to removable portion 150; and a connector for a Network Auxiliary (“Aux”) corresponding to removable portion 160. In this illustrative implementation, only the connectors 200, 202 and 204 for the Routers and the Internal Alarm are used. Therefore, only the corresponding removable portions 140, 142 and 150 are removed to enable insertion of these connectors. The remaining removable portions 110, 120, 130, 160 and 162 remain intact to provide coverage for areas (e.g., openings) associated with (by being either on or adjacent to) the electronic system, where no system connector is being used.

Flexible portion 104 may also comprise additional features. In an illustrative implementation, flexible portion 104 is color coded to identify one or more system connectors. This color coding can be used in addition to or in lieu of the characters on the flexible portion. In another illustrative implementation, flexible portion 104 includes holes, slots, etc. to enable visibility to indicators such as light emitting diode (LED) indicators for the electronic system. For example, the electronic system might be implemented with an indicator associated with the Internal Alarm connector. In that case, an opening is made in the flexible (and rigid portion for that matter) in a location adjacent to the indicator to allow visibility to the indicator. Flexible portion 104 may be further manufactured with an adhesive backing using any suitable adhesive to secure the flexible portion 104 to the rigid portion 102. One example of the adhesive is 9502 Laminating Adhesive, manufactured by 3M. However, skilled artisans will realize that a suitable adhesive material may be used independent of the flexible portion to securedly attach the flexible and rigid portions.

Cover 100 may further comprise openings (e.g., 170) used for securedly attaching the cover to an electronic system using any number of fastener types such as screws, bolts, and the like. Openings 170 at the least extend through the rigid portion 102, and corresponding openings (e.g., holes, notches, etc.) may also extend through flexible portion 104 depending on its size relative to rigid portion 102.

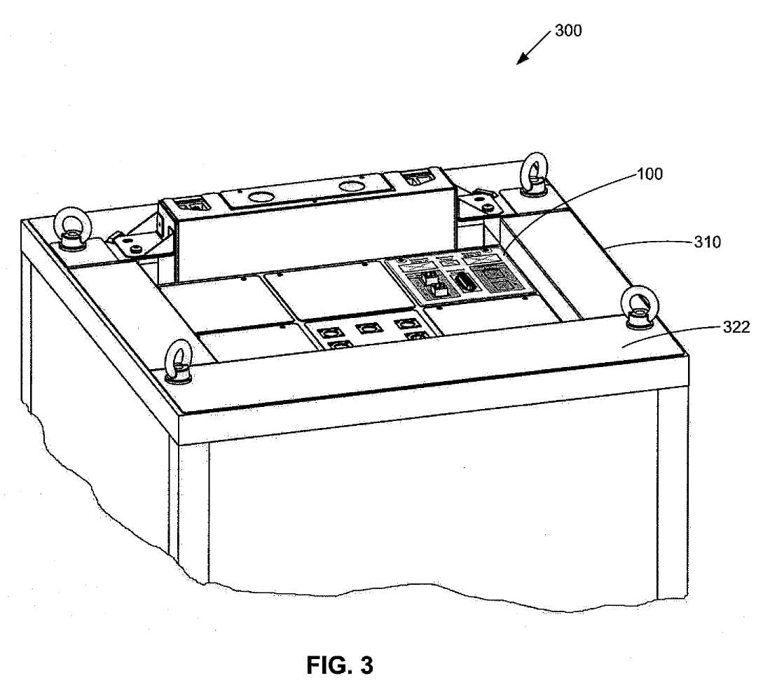

FIG. 3 is a system 300 comprising the cover 100 attached to an electronic system that includes the connectors 200, 202 and 204 coupled thereto. In this embodiment, the electronic system is a radio system or more particularly a base radio for facilitating wireless radio communications. Base radios are well known in the art, so additional details regarding such a system will not be included here for the sake of brevity. Moreover, although this embodiment illustrates a base radio as the electronic system to which cover 100 is attached, cover 100 may be attached to any type of electronic system. As shown, system 300 comprises a housing 310 that at least partially contains or houses the base radio. Housing 310 contains an opening at the top 322 of the housing and adjacent to the connectors 200, 202, 204 over which cover 100 is fastened using screws inserted through holes 170 (FIG. 1 and FIG. 2) and suitably tightened to secure cover 100 in place.

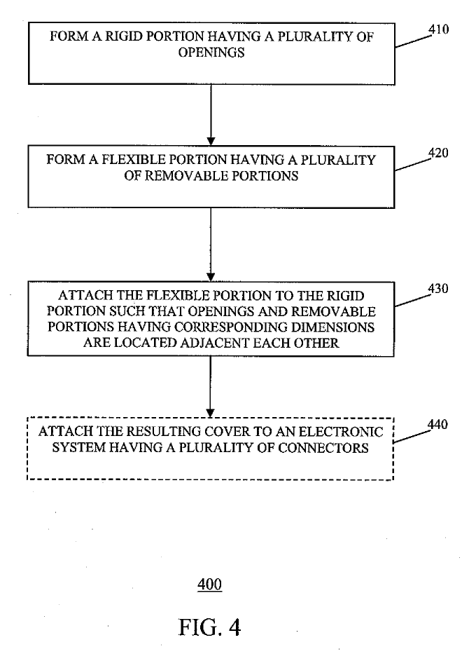

Turning now to FIG. 4, a method in accordance with some embodiments is shown and generally indicated at 400. Using method 400, a cover in accordance with the teachings herein that can be configurable for use with a variety of system implementations is manufactured using any suitable manufacturing process such as, for instance, a manufacturing process that includes casting and die tools. At 410 a rigid portion is formed, for example, by being cast from a suitable metal or metal alloy. Its dimensions provide suitable coverage for the area of the electronic system (e.g., the housing) to which the rigid portion is to be securedly attached. A plurality of openings is bored through the rigid portion through which connectors for the electronic system may extend.

At 420, the flexible portion is formed, for example, by being cut from a sheet of suitable material like LEXAN® and a machine used to cut, stamp, etc., perforations around the perimeter of each removable portion. If color coding, characters, and openings for indicators or fasteners are used, these features may be added to or formed in/on the flexible portion as needed or desired for a given implementation. The flexible portion is then (at 430) aligned with and attached to the rigid portion, such that at least some of the removable portions are each located adjacent an opening in the rigid portion having a corresponding dimension associated with a given system connector. Where the flexible portion comprises the adhesive, the flexible portion may further include a paper attached to the adhesive to protect its adhesive properties until it is removed to allow the adhesive to be used to attach the flexible portion to the rigid portion. In another implementation the flexible portion has no adhesive and a suitable adhesive is applied between the flexible and rigid portions to attach them together.

In further accordance with method 400, the cover 100 may be attached (at 440) to an electronic device having a plurality of connectors associated therewith. In this regards in general, at least one of the removable portions is removed leaving a corresponding opening in the flexible portion, and the cover is mounted on the electronic system such that one of the connectors extends through each opening in the flexible portion and the corresponding opening in the rigid portion, wherein the order of these steps is interchangeable. For example, in one illustrative implementation: the cover 100 is aligned with and secured/fastened to the electronic system/housing using any suitable fasteners, such as screws; some removable portions are removed; and the connectors are inserted through respective openings in the cover and secured (e.g., snapped, screwed, etc.) to the top of the cover. In another illustrative implementation: the connectors are already coupled to the electronic system; some removable portions are removed; and the cover is aligned with and mounted over the connectors.

Method 400 for manufacturing a connector opening cover results in some cost advantages over other techniques for covering connector openings on an electronic device including, but not limited to, the following. For example, tooling costs associated with method 400 are on the magnitude of about one tenth that of the tooling costs associated with the plastic plug method described above. In addition, costs associated with tracking and stocking the individual plastic plugs and the time spent determining the structure of how these plugs are to be used for a given electronic device implementation are essentially eliminated if method 400 is used. Of course, additional advantages may also be had in association with the teachings described herein.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. A cover for an electronic system, the cover comprising:
a rigid portion comprising a plurality of openings formed through the rigid portion; and
a flexible portion attached to the rigid portion and comprising a plurality of corresponding removable portions that are located adjacent the plurality of openings, wherein each of at least a subset of the plurality of openings and the corresponding adjacent removable portions have dimensions that correspond to dimensions of a different connector for an electronic system such that removing the corresponding removable portion allows insertion of the corresponding connector through the cover.

2. The cover of claim 1, wherein the flexible portion further comprises a set of characters that identifies at least one of the connectors for the electronic system.

3. The cover of claim 1, wherein the flexible portion is color coded to identify at least one of the connectors for the electronic system.

4. The cover of claim 1, wherein the flexible portion is comprised of a plastic material.

5. The cover of claim 4, wherein the plastic material is a polycarbonate material.

6. The cover of claim 1, wherein the flexible portion further comprises an adhesive material attaching the flexible portion to the rigid portion.

7. The cover of claim 1, wherein the flexible portion comprises a plurality of perforations around a perimeter of each removable portion to enable its removal.

8. A system comprising:
an electronic system having a plurality of connectors; and
a cover for the electronic system, the cover comprising:
a rigid portion comprising a plurality of openings formed through the rigid portion; and
a flexible portion attached to the rigid portion and comprising a plurality of corresponding removable portions that are located adjacent the plurality of openings, wherein each of at least a subset of the plurality of openings and the corresponding adjacent removable portions have dimensions that correspond to dimensions of a different one of the connectors, and wherein some of the plurality of removable portions are removed to allow insertion of the plurality of connectors through the cover, and some of the removable portions cover areas associated with the electronic system.

9. The system of claim 8, wherein the electronic system comprises a radio system.

10. The system of claim 8, wherein the flexible portion further comprises a set of characters that identifies at least one of the plurality of connectors.

11. The system of claim 8, wherein the flexible portion is color coded to identify at least one of the plurality of connectors.

12. The system of claim 8, wherein the flexible portion is comprised of a plastic material.

13. The system of claim 12, wherein the plastic material is a polycarbonate material.

14. The system of claim 8 further comprising an adhesive material attaching the flexible portion to the rigid portion.

15. The system of claim 8 further comprising a housing that contains at least a portion of the electronic system and that includes an opening located adjacent the plurality of connectors, wherein the cover is securedly attached over the opening in the housing.

16. A method comprising:
forming a rigid portion comprising a plurality of openings formed through the rigid portion;
forming a flexible portion comprising a plurality of removable portions; and
attaching the flexible portion to the rigid portion such that the plurality of removable portions are located adjacent the plurality of openings, wherein each of at least a subset of the plurality of openings and the corresponding adjacent removable portions have dimensions that correspond to dimensions of a different connector for an electronic system such that removing the corresponding removable portion allows insertion of the corresponding connector through the cover.

17. The method of claim 16 further comprising forming a set of characters that identifies at least one of the connectors for the electronic system.

18. The method of claim 16 further comprising color coding the flexible portion to identify at least one of the connectors for the electronic system.

19. The method of claim 16 further comprising attaching the cover to the electronic system.

20. The method of claim 19, wherein attaching the cover to the electronic system comprises:
removing at least one of the removable portions leaving a corresponding opening in the flexible portion; and
mounting the cover on the electronic system such that one of the connectors extends through each opening in the flexible portion and the corresponding opening in the rigid portion.
